(19) United States
(12) Patent Application Publication
(10) Pub. No.: US 2024/0160103 A1
(43) Pub. Date: May 16, 2024

(54) PHOTOSENSITIVE RESIN COMPOSITION, PHOTOSENSITIVE ELEMENT, PRINTED WIRING BOARD, AND METHOD FOR MANUFACTURING PRINTED WIRING BOARD

(71) Applicant: Resonac Corporation, Tokyo (JP)

(72) Inventors: Shuji NOMOTO, Tokyo (JP); Hayato SAWAMOTO, Tokyo (JP); Naoki YAMASHITA, Tokyo (JP)

(21) Appl. No.: 18/550,826

(22) PCT Filed: Jan. 18, 2023
(86) PCT No.: PCT/JP2023/001385

§ 371 Date: Sep. 15, 2023

(30) Foreign Application Priority Data
Jan. 19, 2022 (WO) PCT/JP2022/001765

(51) Int. Cl. G03F 7/075; G03F 7/033

(52) U.S. Cl. CPC G03F 7/0752; G03F 7/033

(57) ABSTRACT

The present disclosure relates to a photosensitive resin composition for a permanent resist, the photosensitive resin composition containing (A) an acid-modified vinyl group-containing resin, (B) an elastomer, (C) a photopolymerization initiator, (D) a curing agent, and (E) an inorganic filler including a surface-treated filler.

### TECHNICAL FIELD

The present disclosure relates to a photosensitive resin composition for a permanent resist, a photosensitive element, a printed wiring board, and a method for manufacturing a printed wiring board.

### BACKGROUND ART

Along with the performance improvement of various electronic instruments, high integration of semiconductors is in progress. Accordingly, various performances are required for permanent resists (solder resists) formed in printed wiring boards, semiconductor package substrates, and the like.

Regarding a photosensitive resin composition used for forming a permanent resist, for example, a photocurable resin composition including an acid-modified vinyl group-containing epoxy resin, an elastomer, a photopolymerization initiator, a diluent, and a curing agent as essential components is known (see Patent Literature 1).

### CITATION LIST

### Patent Literature

Patent Literature 1: JP H11-240930 A

### SUMMARY OF INVENTION

### Technical Problem

Along with miniaturization and performance improvement of package substrates, permanent resists are required to have improved thermal shock resistance (TCT resistance). Furthermore, along with narrowing of the pitch of wiring resulting from higher integration of semiconductor elements, permanent resists are required to have excellent resistance to highly accelerated stress test (HAST resistance).

It is an object of the present disclosure to provide a photosensitive resin composition capable of forming a permanent resist having excellent TCT resistance and HAST resistance, a photosensitive element employing the photosensitive resin composition, a printed wiring board, and a method for producing a printed wiring board.

### Solution to Problem

An aspect of the present disclosure relates to a photosensitive resin composition for a permanent resist, the photosensitive resin composition containing (A) an acid-modified vinyl group-containing resin, (B) an elastomer, (C) a photopolymerization initiator, (D) a curing agent, and (E) an inorganic filler, in which the inorganic filler includes a surface-treated filler.

Another aspect of the present disclosure relates to a photosensitive element including a support film and a photosensitive layer formed on the support film, in which the photosensitive layer includes the above-mentioned photosensitive resin composition.

Still another aspect of the present disclosure relates to a printed wiring board provided with a permanent resist including a cured product of the above-mentioned photosensitive resin composition.

Still another aspect of the present disclosure relates to a method for producing a printed wiring board, the method including: a step of forming a photosensitive layer on a substrate by using the above-mentioned photosensitive resin composition or photosensitive element; a step of exposing and developing the photosensitive layer to form a resist pattern; and a step of curing the resist pattern to form a permanent resist.

### Advantageous Effects of Invention

According to the present disclosure, a photosensitive resin composition capable of forming a permanent resist having excellent TCT resistance and HAST resistance, a photosensitive element employing the photosensitive resin composition, a printed wiring board, and a method for producing a printed wiring board can be provided.

### BRIEF DESCRIPTION OF DRAWINGS

FIG. 1 is a cross-sectional view schematically illustrating a photosensitive element according to the present embodiment.

### DESCRIPTION OF EMBODIMENTS

Matters related to a photosensitive resin composition according to embodiments of the present disclosure, a photosensitive element employing the photosensitive resin composition, a printed wiring board, and a method for producing a printed wiring board will be described below.
[1] A photosensitive resin composition for a permanent resist, the photosensitive resin composition containing (A) an acid-modified vinyl group-containing resin, (B) an elastomer, (C) a photopolymerization initiator, (D) a curing agent, and (E) an inorganic filler, in which the inorganic filler includes a surface-treated filler.
[2] The photosensitive resin composition according to the item [1], in which the surface-treated filler has a photoreactive functional group or a thermoreactive functional group.
[3] The photosensitive resin composition according to the item [1] or [2], in which the surface-treated filler has at least one group selected from the group consisting of a (meth)acryloyl group, a vinyl group, an epoxy group, and a phenylamino group.
[4] The photosensitive resin composition according to any one of the items [1] to [3], in which the surface-treated filler is a surface-treated silica filler.
[5] The photosensitive resin composition according to any one of the items [1] to [4], in which a content of the surface-treated filler is 7% to 28% by mass based on a total solid content of the photosensitive resin composition.
[6] The photosensitive resin composition according to the item [4] or [5], in which the inorganic filler includes the surface-treated silica filler and barium sulfate.
[7] The photosensitive resin composition according to the item [6], in which the surface-treated silica filler has a (meth)acryloyl group, an epoxy group, or a phenylamino group.
[8] The photosensitive resin composition according to the item [6], in which the surface-treated silica filler has a (meth)acryloyl group.
[9] A photosensitive element including a support film and a photosensitive layer formed on the support film, in which the photosensitive layer includes the photosensitive resin composition according to any one of the items [1] to [8].
[10] A printed wiring board provided with a permanent resist including a cured product of the photosensitive resin composition according to any one of the items [1] to [8].
[11] A method for producing a printed wiring board, the method including: a step of forming a photosensitive layer on a substrate by using the photosensitive resin composition according to any one of the items [1] to [8] or the photosensitive element according to the item [9]; a step of exposing and developing the photosensitive layer to form a resist pattern; and a step of curing the resist pattern to form a permanent resist.

Hereinafter, the present disclosure will be described in detail. According to the present specification, the term “step” includes not only an independent step but also a step that cannot be clearly distinguished from other steps, as long as an intended action of the step is achieved. The term “layer” includes a shape structure formed over the entire surface as well as a shape structure formed partially when observed as a plan view. A numerical value range indicated by using the term “to” represents a range including the numerical values described before and after the term “to” as the minimum value and the maximum value, respectively. With regard to a numerical value range described stepwise in the present specification, the upper limit value or lower limit value of a numerical value range of a certain stage may be replaced with the upper limit value or lower limit value of a numerical value range of another stage. With regard to a numerical value range described in the present specification, the upper limit value or lower limit value of the numerical value range may be replaced with a value shown in Examples.

When the amount of each component in the composition is mentioned in the present specification, in a case where a plurality of substances corresponding to each component are present in the composition, unless particularly stated otherwise, the amount means the total amount of the plurality of substances present in the composition.

In the present specification, the term “(meth)acrylate” means at least one of “acrylate” and “methacrylate” corresponding thereto, and the same also applies to other similar expressions such as (meth)acrylic acid and (meth)acryloyl. In the present specification, the term “solid content” refers to non-volatile components excluding volatile substances (water, solvents, and the like) included in the photosensitive resin composition and also includes liquid, syrup-like, or wax-like components at room temperature (near 25° C.).

[Photosensitive Resin Composition]

The photosensitive resin composition for a permanent resist according to the present embodiment includes (A) an acid-modified vinyl group-containing resin, (B) an elastomer, (C) a photopolymerization initiator, (D) a curing agent, and (E) an inorganic filler, and the inorganic filler includes a surface-treated filler. The photosensitive resin composition according to the present embodiment is a negative-type photosensitive resin composition, and a cured film of the photosensitive resin composition can be used as a permanent resist having excellent TCT resistance and HAST resistance. Each component used in the photosensitive resin composition of the present embodiment will be described in more detail below.

(Component (A): Acid-Modified Vinyl Group-Containing Resin)

The photosensitive resin composition according to the present embodiment contains an acid-modified vinyl group-containing resin as component (A). The acid-modified vinyl group-containing resin is not particularly limited as long as it has a vinyl group that is a photopolymerizable ethylenically unsaturated bond, and an alkali-soluble acidic group. Examples of the acidic group carried by the acid-modified vinyl group-containing resin include a carboxy group, a sulfo group, and a phenolic hydroxyl group. Among these, a carboxy group is preferred from the viewpoint of resolution.

As the acid-modified vinyl group-containing resin, for example, an acid-modified epoxy (meth)acrylate may be mentioned. The acid-modified epoxy (meth)acrylate is a resin obtained by acid-modifying an epoxy (meth)acrylate, which is a reaction product of an epoxy resin and an organic acid having a vinyl group. As the acid-modified epoxy (meth)acrylate, for example, an addition reaction product obtained by adding a saturated or unsaturated polybasic acid anhydride (c) to an esterification product obtained by reacting an epoxy resin (a) with a vinyl group-containing monocarboxylic acid (b), can be used.

Examples of the epoxy resin (a) include a bisphenol novolac type epoxy resin, a novolac type epoxy resin, a bisphenol A type epoxy resin, a bisphenol F type epoxy resin, a triphenolmethane type epoxy resin, a biphenyl type epoxy resin, a naphthalene type epoxy resin, and a dicyclopentadiene type epoxy resin.

Examples of the vinyl group-containing monocarboxylic acid (b) include acrylic acid derivatives such as acrylic acid, a dimer of acrylic acid, methacrylic acid, β-furfurylacrylic acid, β-styrylacrylic acid, cinnamic acid, crotonic acid, and α-cyanocinnamic acid; a hemiester compound that is a reaction product of a hydroxyl group-containing (meth)acrylate and a dibasic acid anhydride; and a hemiester compound that is a reaction product of a vinyl group-containing monoglycidyl ether or a vinyl group-containing monoglycidyl ester and a dibasic acid anhydride.

Examples of the hydroxyl group-containing (meth)acrylate, vinyl group-containing monoglycidyl ether, and vinyl group-containing monoglycidyl ester include hydroxyethyl acrylate, hydroxyethyl methacrylate, hydroxypropyl acrylate, hydroxypropyl methacrylate, hydroxybutyl acrylate, hydroxybutyl methacrylate, polyethylene glycol monoacrylate, polyethylene glycol monomethacrylate, trimethylolpropane diacrylate, trimethylolpropane dimethacrylate, pentaerythritol triacrylate, pentaerythritol trimethacrylate, dipentaerythritol pentaacrylate, pentaerythritol pentamethacrylate, glycidyl acrylate, and glycidyl methacrylate.

Examples of the dibasic acid anhydride include succinic anhydride, maleic anhydride, tetrahydrophthalic anhydride, phthalic anhydride, methyltetrahydrophthalic anhydride, ethyltetrahydrophthalic anhydride, hexahydrophthalic anhydride, methylhexahydrophthalic anhydride, ethylhexahydrophthalic anhydride, and itaconic anhydride.

Examples of the saturated or unsaturated polybasic acid anhydride (c) include succinic anhydride, maleic anhydride, tetrahydrophthalic anhydride, phthalic anhydride, methyltetrahydrophthalic anhydride, ethyltetrahydrophthalic anhydride, hexahydrophthalic anhydride, methylhexahydrophthalic anhydride, ethylhexahydrophthalic anhydride, and itaconic anhydride. Among these, from the viewpoint of obtaining a photosensitive resin composition capable of forming a pattern with excellent resolution, tetrahydrophthalic anhydride may be used.

The acid value of the component (A) is not particularly limited. From the viewpoint of improving the solubility of an unexposed part in an alkali aqueous solution, the acid value of the component (A) may be 30 mg KOH/g or more, 40 mg KOH/g or more, or 50 mg KOH/g or more. From the viewpoint of improving the electrical characteristics of the cured film, the acid value of the component (A) may be 150 mg KOH/g or less, 120 mg KOH/g or less, or 100 mg KOH/g or less.

The weight average molecular weight (Mw) of the component (A) is not particularly limited. From the viewpoint of improving the close adhesiveness to the cured film, the Mw of the component (A) may be 3000 or more, 4000 or more, or 5000 or more. From the viewpoint of improving the resolution of the photosensitive layer, the Mw of the component (A) may be 30000 or less, 25000 or less, or 18000 or less. The Mw can be measured by a gel permeation chromatography (GPC) method.

From the viewpoint of improving the heat resistance, electrical characteristics, and chemical resistance of the permanent resist, the content of the component (A) in the photosensitive resin composition may be 20% to 70% by mass, 25% to 60% by mass, 30% to 50% by mass, or 32% to 45% by mass, based on the total solid content of the photosensitive resin composition.

(Component (B): Elastomer)

As the photosensitive resin composition according to the present embodiment contains an elastomer as component (B), deterioration in the flexibility and adhesive strength caused by distortion (internal stress) inside the resin due to curing shrinkage of the component (A) can be suppressed.

Examples of the component (B) include a styrene-based elastomer, an olefin-based elastomer, a urethane-based elastomer, a polyester-based elastomer, a polyamide-based elastomer, an acrylic elastomer, and a silicone-based elastomer. These elastomers are composed of a hard segment component contributing to heat resistance and strength, and a soft segment component contributing to pliability and toughness.

Examples of the styrene-based elastomer include a styrene-butadiene-styrene block copolymer, a styrene-isoprene-styrene block copolymer, a styrene-ethylene-butylene-styrene block copolymer, and a styrene-ethylene-propylene-styrene block copolymer. As the component constituting the styrene-based elastomer, in addition to styrene, styrene derivatives such as α-methylstyrene, 3-methylstyrene, 4-propylstyrene, and 4-cyclohexylstyrene can be used.

Examples of the olefin-based elastomer include an ethylene-propylene copolymer, an ethylene-α-olefin copolymer, an ethylene-α-olefin-non-conjugated diene copolymer, a propylene-α-olefin copolymer, a butene-α-olefin copolymer, an ethylene-propylene-diene copolymer; copolymers of non-conjugated dienes such as a dicyclopentadiene, 1,4-hexadiene, cyclooctadiene, methylenenorbornene, ethylidene norbornene, butadiene, and isoprene with α-olefins; and a carboxylic acid-modified butadiene-acrylonitrile copolymer.

As the urethane-based elastomer, a compound consisting of a hard segment composed of a low-molecular weight (short-chain) diol and a diisocyanate and a soft segment composed of a polymeric (long-chain) diol and a diisocyanate, can be used.

Examples of a short-chain diol include ethylene glycol, propylene glycol, 1,4-butanediol, and bisphenol A. The number average molecular weight of the short-chain diol is preferably 48 to 500.

Examples of a long-chain diol include polypropylene glycol, polytetramethylene oxide, poly(1,4-butylene adipate), poly(ethylene-1,4-butylene adipate), polycaprolactone, poly(1,6-hexylene carbonate), and poly(1,6-hexylene-neopentylene adipate). The number average molecular weight of the long-chain diol is preferably 500 to 10000.

As the polyester-based elastomer, a compound obtained by polycondensing a dicarboxylic acid or a derivative thereof and a diol compound or a derivative thereof can be used.

Examples of the dicarboxylic acid include aromatic dicarboxylic acids such as terephthalic acid, isophthalic acid, and naphthalenedicarboxylic acid; aliphatic dicarboxylic acids having 2 to 20 carbon atoms, such as adipic acid, sebacic acid, and dodecanedicarboxylic acid; and alicyclic dicarboxylic acids such as cyclohexanedicarboxylic acid. Regarding the dicarboxylic acid, one kind thereof can be used alone, or two or more kinds thereof can be used in combination.

Examples of the diol compound include aliphatic diols such as ethylene glycol, 1,3-propanediol, 1,4-butanediol, 1,6-hexanediol, and 1,10-decanediol; alicyclic diols such as 1,4-cyclohexanediol; and aromatic diols such as bisphenol A, bis-(4-hydroxyphenyl)methane, bis-(4-hydroxy-3-methylphenyl)propane, and resorcin.

As the polyester-based elastomer, a multi-block copolymer employing an aromatic polyester (for example, polybutylene terephthalate) as a hard segment component and an aliphatic polyester (for example, polytetramethylene glycol) as a soft segment component can be used. Polyester-based elastomers of various grades are available depending on the types, ratios, and differences in the molecular weights of the hard segment and the soft segment.

The polyamide-based elastomer is broadly classified into two types, namely, a polyether-block-amide type and a polyether ester-block-amide type, which use a polyamide as the hard segment and a polyether or a polyester as the soft segment. Examples of the polyamide include polyamide-6, polyamide-11, and polyamide-12. Examples of the polyether include polyoxyethylene glycol, polyoxypropylene glycol, and polytetramethylene glycol.

As the acrylic elastomer, a compound including a constituent unit based on a (meth)acrylic acid ester as a main component can be used. Examples of the (meth)acrylic acid ester include methyl (meth)acrylate, ethyl (meth)acrylate, butyl (meth)acrylate, methoxyethyl (meth)acrylate, and ethoxyethyl (meth)acrylate. The acrylic elastomer may be a compound obtained by copolymerizing a (meth)acrylic acid ester and acrylonitrile or may be a compound obtained by further copolymerizing the compound with a monomer having a functional group that serves as a crosslinking point. Examples of the monomer having a functional group include methyl methacrylate, glycidyl methacrylate, and allyl glycidyl ether.

Examples of the acrylic elastomer include an acrylonitrile-butyl acrylate copolymer, an acrylonitrile-butyl acrylate-ethyl acrylate copolymer, a methyl methacrylate-butyl acrylate-methacrylic acid copolymer, and an acrylonitrile-butyl acrylate-glycidyl methacrylate copolymer. As the acrylic elastomer, an acrylonitrile-butyl acrylate-glycidyl methacrylate copolymer or a methyl methacrylate-butyl acrylate-methacrylic acid copolymer is preferred, and a methyl methacrylate-butyl acrylate-methacrylic acid copolymer is more preferred.

The silicone-based elastomer is a compound containing an organopolysiloxane as a main component. Examples of the organopolysiloxane include polydimethylsiloxane, polymethylphenylsiloxane, and polydiphenylsiloxane. The silicon-based elastomer may also be a compound obtained by modifying a portion of an organopolysiloxane with a vinyl group, an alkoxy group, or the like.

From the viewpoint of improving the close adhesiveness of the cured film, the component (B) may include a carboxylic acid-modified butadiene-acrylonitrile copolymer or a polyester-based elastomer having a hydroxyl group.

The content of the component (B) may be 2 to 50 parts by mass, 4 to 45 parts by mass, 6 to 40 parts by mass, or 10 to 35 parts by mass, with respect to 100 parts by mass of the component (A). When the content of the component (B) is within the above-described range, the elastic modulus of the cured film in a high-temperature region is lowered, and an unexposed part is more easily eluted with a liquid developer.

(Component (C): Photopolymerization Initiator)

The photopolymerization initiator as component (C) is not particularly limited as long as it is capable of polymerizing the component (A). Regarding the component (C), one kind thereof may be used alone, or two or more kinds thereof may be used in combination.

Examples of the component (C) include benzoin compounds such as benzoin, benzoin methyl ether, and benzoin isopropyl ether; acetophenone compounds such as acetophenone, 2,2-dimethoxy-2-phenylacetophenone, 2,2-diethoxy-2-phenylacetophenone, 1,1-dichloroacetophenone, 1-hydroxycyclohexyl phenyl ketone, 2-benzyl-2-dimethylamino-1-(4-morpholinophenyl)-butanone-1,2-methyl-[4-(methylthio)phenyl]-2-morpholino-1-propane, and N,N-dimethylaminoacetophenone; anthraquinone compounds such as 2-methylanthraquinone, 2-ethylanthraquinone, 2-tert-butylanthraquinone, 1-chloro anthraquinone, 2-amylanthraquinone, and 2-aminoanthraquinone; thioxanthone compounds such as 2,4-dimethylthioxanthone, 2,4-diethylthioxanthone, 2-chlorothioxanthone, and 2,4-diisopropylthioxanthone; ketal compounds such as acetophenone dimethyl ketal and benzyl dimethyl ketal; benzophenone compounds such as benzophenone, methylbenzophenone, 4,4′-dichlorobenzophenone, 4,4′-bis(diethylamino)benzophenone, Michler's ketone, and 4-benzoyl-4′-methyldiphenyl sulfide; imidazole compounds such as 2-(o-chlorophenyl)-4,5-diphenylimidazole dimer, 2-(o-chlorophenyl)-4,5-di(m-methoxyphenyl)imidazoledimer, 2-(o-fluorophenyl)-4,5-diphenylimidazoledimer, 2-(o-methoxyphenyl)-4,5-diphenylimidazole dimer, 2-(p-methoxyphenyl)-4,5-diphenylimidazole dimer, 2,4-di(p-methoxyphenyl)-5-phenylimidazole dimer, and 2-(2,4-dimethoxyphenyl)-4,5-diphenylimidazole dimer; acridine compounds such as 9-phenylacridine and 1,7-bis(9,9′-acridinyl)heptane; acylphosphine oxide compounds such as 2,4,6-trimethylbenzoyldiphenylphosphine oxide; oxime ester compounds such as 1,2-octanedione-1-[4-(phenylthio)phenyl]-2-(0-benzoyloxime), 1-[9-ethyl-6-(2-methylbenzoyl)-9H-carbazol-3-yl]ethanone 1-(O-acetyloxime), and 1-phenyl-1,2-propanedione-2-[0-(ethoxycarbonyl)oxime]; and tertiary amine compounds such as N,N-dimethylaminobenzoic acid ethyl ester, N,N-dimethylaminobenzoic acid isoamyl ester, pentyl-4-dimethylaminobenzoate, triethylamine, and triethanolamine

The content of the component (C) in the photosensitive resin composition is not particularly limited; however, the content may be 0.2% to 15% by mass, 0.5% to 10% by mass, or 1% to 5% by mass, based on the total solid content of the photosensitive resin composition.

(Component (D): Curing Agent)

As the curing agent that is component (D), a compound that is cured per se by heat, ultraviolet radiation, or the like, or a compound that is cured by reacting with an acidic group of the component (A) under heat, ultraviolet radiation, or the like, can be used. By using the component (D), the heat resistance, adhesiveness, chemical resistance, and the like of a cured film (permanent resist) formed from the photosensitive resin composition can be improved.

Examples of the component (D) include thermally curable compounds such as an epoxy compound, a melamine compound, a urea compound, an oxazoline compound, and a block-type isocyanate. Regarding the component (D), one kind thereof may be used alone, or two or more kinds thereof may be used in combination.

Examples of the epoxy compound include a bisphenol A type epoxy resin, a bisphenol F type epoxy resin, a hydrogenated bisphenol A type epoxy resin, a brominated bisphenol A type epoxy resin, a novolac type epoxy resin, a bisphenol S type epoxy resin, a biphenyl type epoxy resin, a naphthalene type epoxy resin, a dicyclo type epoxy resin, a hydantoin type epoxy resin, triglycidyl isocyanurate, and a bixylenol type epoxy resin. Examples of the melamine compound include triaminotriazine, hexamethoxymelamine, and hexabutoxylated melamine Examples of the urea compound include dimethylolurea.

The content of the component (D) may be 2% to 30% by mass, 5% to 25% by mass, or 10% to 20% by mass, based on the total solid content of the photosensitive resin composition. When the content of the component (D) is within the above-described range, heat resistance of the formed cured film can be further improved while maintaining satisfactory developability.

(Component (E): Inorganic Filler)

The photosensitive resin composition according to the present embodiment contains an inorganic filler including a surface-treated filler as component (E). A surface-treated filler can be obtained by treating the surface of an inorganic filler with a surface treatment agent such as an organic silane compound. By treating the surface of an inorganic filler, the adhesive strength to the component (A) at the filler interface is improved, and the TCT resistance and HAST resistance of a cured film of the photosensitive resin composition can be improved. Regarding the surface-treated filler, one kind thereof may be used alone, or two or more kinds thereof may be used in combination.

Examples of the inorganic filler include silica, alumina, titania, tantalum oxide, zirconia, silicon nitride, gallium oxide, and boron nitride.

As the surface treatment agent, from the viewpoint of further improving the TCT resistance, an organic silane compound such as an epoxysilane compound, an aminosilane compound, a (meth)acrylsilane compound, and a vinylsilane compound may be used.

Examples of the organic silane compound include 3-aminopropyltrimethoxysilane, 3-aminopropyltriethoxysilane, 3-(2-aminoethyl)aminopropyltrimethoxysilane, 3-(2-aminoethypaminopropylmethyldimethoxysilane, 3-phenylaminopropyltrimethoxysilane, 3-glycidoxypropyltrimethoxysilane, 3-glycidoxypropylmethyldimethoxysilane, 3-glycidoxypropyltriethoxysilane, 3-glycidoxypropylmethyldiethoxysilane, vinyltriacetoxysilane, vinyltrimethoxysilane, vinyltriethoxysilane, vinyltriisopropoxysilane, allyltrimethoxysilane, diallyldimethylsilane, 3-methacryloxypropyltrimethoxysilane, 3-methacryloxypropylmethyldimethoxysilane, 3-methacryloxypropyltriethoxysilane, 3-mercaptopropyltrimethoxysilane, 3-mercaptopropylmethyldimethoxysilane, 3-mercaptopropyltriethoxysilane, N-(1,3-dimethylbutylidene)-3-aminopropyltriethoxysilane, 2-(3,4-epoxycyclohexyl)ethyltrimethoxysilane, tris(trimethoxysilylpropyl) isocyanurate, and 3-isocyanatopropyltriethoxysilane.

It is preferable that the surface-treated filler has a photoreactive functional group or a thermoreactive functional group. By using a surface-treated filler having a photoreactive functional group or a thermoreactive functional group, the adhesive strength between the component (A) and the component (E) can be increased.

Examples of the photoreactive functional group include a (meth)acryloyl group and a vinyl group. Examples of the thermoreactive functional group include an epoxy group, an amino group, a phenylamino group, an isocyanate group, and a mercapto group. It is preferable that the surface-treated filler according to the present embodiment has at least one kind of group selected from the group consisting of a (meth)acryloyl group, a vinyl group, an epoxy group, and a phenylamino group.

From the viewpoint of improving dispersibility and adhesive strength, the surface-treated filler is preferably a filler obtained by surface-treating silica, alumina, titania, or boron nitride, more preferably a filler obtained by surface-treating silica, alumina, or boron nitride, and even more preferably a surface-treated silica filler. From the viewpoint of improving the low-expansion properties and heat resistance, it is preferable that the component (E) includes a surface-treated silica filler; it is more preferable that the component (E) includes a silica filler having at least one kind of group selected from the group consisting of a (meth)acryloyl group, a vinyl group, an epoxy group, and a phenylamino group; it is even more preferable that the component (E) includes a surface-treated silica filler having a (meth)acryloyl group, an epoxy group, or a phenylamino group; and it is still more preferable that the component (E) includes a surface-treated silica filler having a (meth)acryloyl group.

The content of the surface-treated filler may be 5% by mass or more, 6% by mass or more, 7% by mass or more, 8% by mass or more, 9% by mass or more, or 10% by mass or more, and may be 35% by mass or less, 30% by mass or less, 28% by mass or less, 25% by mass or less, 20% by mass or less, or 15% by mass or less, based on the total solid content of the photosensitive resin composition. From the viewpoints of resolution and low coefficient of thermal expansion, the content of the surface-treated filler may be 5% to 35% by mass, 6% to 30% by mass, 7% to 28% by mass, 8% to 25% by mass, 9% to 20% by mass, or 10% to 15% by mass, based on the total solid content of the photosensitive resin composition. When the content of the surface-treated filler is within the above-described range, the low coefficient of thermal expansion, heat resistance, insulation reliability, thermal shock resistance, resolution, film strength, and the like can be further improved.

From the viewpoint of resolution, the average particle size of the surface-treated filler may be 0.01 μm or more, 0.1 μm or more, or 0.2 or more and may be 5.0 μm or less, 4.0 μm or less, or 3.0 μm or less.

The component (E) may further include an inorganic filler other than the above-mentioned surface-treated filler. Examples of the inorganic filler include barium titanate, barium carbonate, magnesium carbonate, aluminum hydroxide, magnesium hydroxide, lead titanate, lead zirconate titanate, lead lanthanum zirconate titanate, gallium oxide, spinel, mullite, cordierite, talc, aluminum titanate, yttria-containing zirconia, barium sulfate, barium silicate, calcium carbonate, calcium sulfate, zinc oxide, and magnesium titanate. The inorganic filler may be surface-treated.

From the viewpoint of improving resolution, the component (E) may further include barium sulfate. From the viewpoint of improving photosensitivity, the component (E) may include surface-treated silica filler and barium sulfate, it is preferable that the component (E) includes barium sulfate and a surface-treated silica filler having a (meth)acryloyl group, an epoxy group, or a phenylamino group, and it is more preferable that the component (E) includes barium sulfate and a surface-treated silica filler having a (meth)acryloyl group. Barium sulfate may be surface-treated.

The content of barium sulfate may be 5% to 30% by mass, 10% to 25% by mass, 12% to 20% by mass, or 14% to 18% by mass, based on the total solid content of the photosensitive resin composition.

(Component (F): Photopolymerizable Compound)

From the viewpoint of improving sensitivity and resolution, the photosensitive resin composition according to the present embodiment may further contain a photopolymerizable compound having no acidic group as component (F). Regarding the component (F), one kind thereof may be used alone, or two or more kinds thereof may be used in combination.

Examples of the component (F) include hydroxyalkyl (meth)acrylates such as 2-hydroxyethyl (meth)acrylate and 2-hydroxypropyl (meth)acrylate; mono- or di(meth)acrylates of glycols such as ethylene glycol, methoxytetraethylene glycol, and polyethylene glycol; (meth)acrylamide compounds such as N,N-dimethyl (meth)acrylamide and N-methylol (meth)acrylamide; aminoalkyl (meth)acrylates such as N,N-dimethylaminoethyl (meth)acrylate; polyvalent (meth)acrylates of polyhydric alcohols such as hexanediol, trimethylolpropane, pentaerythritol, ditrimethylolpropane, dipentaerythritol, and trishydroxyethyl isocyanurate, or ethylene oxide or propylene oxide adduct thereof; (meth)acrylate compounds of ethylene oxide or propylene oxide adducts of phenol compounds such as phenoxyethyl (meth)acrylate, polyethoxydi(meth)acrylate of bisphenol A; (meth)acrylate compounds of glycidyl ethers such as glycerin diglycidyl ether, trimethylolpropane triglycidyl ether, and triglycidyl isocyanurate; and melamine (meth)acrylate.

From the viewpoint of increasing the crosslink density by photocuring and improving the heat resistance and electrical insulation properties, the component (F) may include a photopolymerizable compound having three or more ethylenically unsaturated groups. Examples of the photopolymerizable compound having three or more ethylenically unsaturated groups include trimethylolpropane tri(meth)acrylate, dipentaerythritol tri(meth)acrylate, tetramethylolmethane tri(meth)acrylate, EO-modified trimethylolpropane tri(meth)acrylate, PO-modified trimethylolpropane tri(meth)acrylate, EO- and PO-modified trimethylolpropane tri(meth)acrylate, dipentaerythritol penta(meth)acrylate, tetramethylolmethane tetra(meth)acrylate, and dipentaerythritol hexaacrylate.

(Component (G): Pigment)

The photosensitive resin composition of the present embodiment may further contain a pigment as component (G), from the viewpoint of improving the distinguishability of the production apparatus or appearance. As the component (G), a colorant that develops a desired color can be used when hiding the wiring or the like. Examples of the component (G) include phthalocyanine blue, phthalocyanine green, iodine green, diazo yellow, crystal violet, titanium oxide, carbon black, and naphthalene black.

From the viewpoint of more effectively hiding the wiring, the content of the component (G) may be 0.1% to 10% by mass, 0.5% to 8% by mass, or 1% to 5% by mass, based on the total solid content of the photosensitive resin composition.

(Other Components)

The photosensitive resin composition according to the present embodiment may further contain various additives as necessary.

Examples of the additives include polymerization inhibitors such as hydroquinone, methylhydroquinone, hydroquinone monomethyl ether, catechol, and pyrogallol; thickeners such as bentone and montmorillonite; silicone-based, fluorine-based, and vinyl resin-based antifoaming agents; silane coupling agents; and flame retardants such as a brominated epoxy compound, an acid-modified brominated epoxy compound, an antimony compound, a phosphate compound, an aromatic condensed phosphoric acid ester, and a halogen-containing condensed phosphoric acid ester.

(Solvent)

When the photosensitive resin composition according to the present embodiment contains a solvent for dissolving and dispersing each component, application on a substrate is made easier, and a coating film having a uniform thickness can be formed.

Examples of the solvent include ketones such as methyl ethyl ketone and cyclohexanone; aromatic hydrocarbons such as toluene, xylene, and tetramethylbenzene; glycol ethers such as methyl cellosolve, butyl cellosolve, methyl carbitol, butyl carbitol, propylene glycol monomethyl ether, dipropylene glycol monoethyl ether, dipropylene glycol diethyl ether, and triethylene glycol monoethyl ether; esters such as ethyl acetate, butyl acetate, butyl cellosolve acetate, and carbitol acetate; aliphatic hydrocarbons such as octane and decane; and petroleum-based solvents such as petroleum ether, petroleum naphtha, hydrogenated petroleum naphtha, and solvent naphtha. Regarding the solvent, one kind thereof may be used alone, or two or more kinds thereof may be used in combination.

The blending amount of the solvent is not particularly limited; however, the proportion of the solvent in the photosensitive resin composition may be 10% to 50% by mass, 20% to 40% by mass, or 25% to 35% by mass.

The photosensitive resin composition of the present embodiment can be prepared by uniformly mixing each of the above-mentioned components with a roll mill, a bead mill, or the like.

[Photosensitive Element]

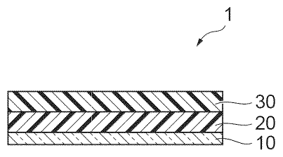

A photosensitive element according to the present embodiment includes a support film and a photosensitive layer including the above-mentioned photosensitive resin composition. FIG. 1 is a cross-sectional view schematically illustrating the photosensitive element according to the present embodiment. As shown in FIG. 1, the photosensitive element 1 includes a support film 10 and a photosensitive layer 20 formed on the support film 10.

The photosensitive element 1 can be fabricated by applying the photosensitive resin composition according to the present embodiment on the support film 10 by a known method such as reverse roll coating, gravure roll coating, comma coating, or curtain coating, and then drying the coating film to form the photosensitive layer 20.

Examples of the support film include a polyester film of polyethylene terephthalate, polybutylene terephthalate, or the like; and a polyolefin film of polypropylene, polyethylene, or the like. The thickness of the support film may be, for example, 5 to 100 μm. The thickness of the photosensitive layer may be, for example, 5 to 50 μm, 5 to 40 μm, or 10 to 30 μm. The surface roughness of the support film is not particularly limited; however, the arithmetic mean roughness Ra may be 1000 nm or less, 500 nm or less, or 250 nm or less.

Regarding drying of the coating film, hot air drying or drying using far-infrared radiation or near-infrared radiation can be used. The drying temperature may be 60° C. to 120° C., 70° C. to 110° C., or 80° C. to 100° C. The drying time may be 1 to 60 minutes, 2 to 30 minutes, or 5 to 20 minutes.

On the photosensitive layer 20, a protective film 30 covering the photosensitive layer 20 may be further provided. The photosensitive element 1 can have the protective film 30 laminated on a surface of the photosensitive layer 20, the surface being on the opposite side of the surface in contact with the support film 10. As the protective film 30, for example, a polymer film of polyethylene, polypropylene, or the like may be used.

[Printed Wiring Board]

A printed wiring board according to the present embodiment is provided with a permanent resist including a cured product of the photosensitive resin composition according to the present embodiment. As a result, the HAST resistance and TCT resistance can be improved.

A method for producing a printed wiring board according to the present embodiment includes a step of forming a photosensitive layer on a substrate by using the above-mentioned photosensitive resin composition or photosensitive element; a step of exposing and developing the photosensitive layer to form a resist pattern; and a step of curing the resist pattern to form a permanent resist. An example of each step will be described below.

First, a substrate such as a copper-clad laminate is prepared, and a photosensitive layer is formed on the substrate. The photosensitive layer may be formed by applying a photosensitive resin composition on a substrate and drying the photosensitive resin composition. Examples of a method of applying a photosensitive resin composition include a screen printing method, a spraying method, a roll coating method, a curtain coating method, and an electrostatic coating method. The drying temperature may be 60° C. to 120° C., 70° C. to 110° C., or 80° C. to 100° C. The drying time may be 1 to 7 minutes, 1 to 6 minutes, or 2 to 5 minutes.

The photosensitive layer may also be formed on a substrate by peeling a protective film from a photosensitive element and then laminating a photosensitive layer. Regarding a method of laminating the photosensitive layer, for example, a method of performing thermal lamination using a laminator may be mentioned.

Next, a negative film is brought into direct contact, or into contact through a support film, with the photosensitive layer, and the photosensitive layer is exposed by irradiating the photosensitive layer with actinic rays. Examples of the actinic rays include an electron beam, ultraviolet radiation, and X-rays, and the actinic rays are preferably ultraviolet radiation. Regarding the light source, a low-pressure mercury lamp, a high-pressure mercury lamp, an ultrahigh-pressure mercury lamp, a halogen lamp, and the like can be used. The exposure dose may be 10 to 2000 mJ/cm², 100 to 1500 mJ/cm², or 300 to 1000 mJ/cm².

After the exposure, a resist pattern is formed by removing unexposed parts with a liquid developer. Examples of a developing method include a dipping method and a spraying method. As the liquid developer, for example, an alkali aqueous solution of potassium hydroxide, sodium hydroxide, sodium carbonate, potassium carbonate, tetramethylammonium hydroxide, or the like can be used.

With regard to a resist pattern, a patterned cured film (permanent resist) can be formed by performing at least one treatment of post-exposure and post-heating. The exposure dose of after-exposure may be 100 to 5000 mJ/cm², 500 to 2000 mJ/cm², or 700 to 1500 J/cm². The heating temperature of post-heating may be 100° C. to 200° C., 120° C. to 180° C., or 135° C. to 165° C. The heating time of post-heating may be 5 minutes to 12 hours, 10 minutes to 6 hours, or 30 minutes to 2 hours.

The permanent resist according to the present embodiment can be used as an interlayer insulating layer or a surface protective layer of a semiconductor element. A semiconductor element including an interlayer insulating layer or a surface protective layer formed from a cured film of the above-mentioned photosensitive resin composition, and an electronic device including the semiconductor element can be fabricated. The semiconductor element may be, for example, a memory, a package, and the like, having a multilayer wiring structure, a rewiring structure, or the like. Examples of the electronic device include a mobile phone, a smartphone, a tablet terminal, a personal computer, and a hard disk suspension. By furnishing a patterned cured film formed from the photosensitive resin composition according to the present embodiment, a semiconductor element and an electronic device having excellent reliability can be provided.

### EXAMPLES

Hereinafter, the present disclosure will be described in more detail by way of Examples; however, the present disclosure is not intended to be limited to these Examples.

### Synthesis Example 1

350 parts by mass of a bisphenol F novolac type epoxy resin (manufactured by DIC Corporation, trade name “EXA-7376”), 70 parts by mass of acrylic acid, 0.5 parts by mass of methylhydroquinone, and 120 parts by mass of carbitol acetate were mixed while being stirred at 90° C. The mixed liquid was cooled to 60° C., 2 parts by mass of triphenylphosphine was added, and the mixture was caused to react at 100° C. until the acid value of the solution became 1 mg KOH/g or less. 98 parts by mass of tetrahydrophthalic anhydride and 85 parts by mass of carbitol acetate were added to the reaction liquid, and the mixture was heated to 80° C. and then was caused to react for 6 hours. Thereafter, the reaction solution was cooled to room temperature (25° C.), and a solution of acid-modified epoxy acrylate (A-1) (solid content concentration: 73% by mass) as component (A) was obtained.

The following materials were prepared as components (B) to (G).
B-1: Polyester-based elastomer having a hydroxyl group (manufactured by Showa Denko Materials Co., Ltd., trade name “ESPEL 1612”)
B-2: Polyester-based elastomer having a hydroxyl group (manufactured by Showa Denko Materials Co., Ltd., trade name “ESPEL 1620”)
B-3: Carboxylic acid-modified butadiene-acrylonitrile copolymer (manufactured by JSR Corporation, trade name “XER-91”)
C-1: 2-Methyl-[4-(methylthio)phenyl]-2-morpholino-1-propane (manufactured by IGM Resins B.V., trade name “Omirad 907”)
C-2: 2,4-Diethylthioxanthone (manufactured by Nippon Kayaku Co., Ltd., trade name “DETX-S”)
D-1: Bisphenol A type epoxy resin (manufactured by Mitsubishi Chemical Corporation, trade name “jER828”)
D-2: Melamine (manufactured by Mitsui Chemicals, Inc.)
E-1: Silica filler having a methacryloyl group (average particle size 0.5 μm) (manufactured by ADMATECHS COMPANY LIMITED)
E-2: Silica filler having a vinyl group (average particle size 0.5 μm) (manufactured by ADMATECHS COMPANY LIMITED)
E-3: Silica filler having an epoxy group (average particle size 0.5 μm) (manufactured by ADMATECHS COMPANY LIMITED)
E-4: Silica filler having a phenylamino group (average particle size 0.5 μm) (manufactured by ADMATECHS COMPANY LIMITED)
E-5: Untreated silica filler (average particle size 0.5 μm) (manufactured by ADMATECHS COMPANY LIMITED, trade name “SO-C2”)
E-6: Barium sulfate (average particle size 1.0 μm) (manufactured by Nippon Solvay K. K., trade name “ASA”)
F-1: Dipentaerythritol hexaacrylate (manufactured by Nippon Kayaku Co., Ltd., trade name “DPHA”)
G-1: Phthalocyanine green

[Photosensitive Resin Composition]

Each component in the blending amount (parts by mass, amount equivalent to solid content) shown in Table 1 or Table 2 was blended, and the mixture was kneaded with a three-roll mill Thereafter, carbitol acetate was added thereto such that the solid content concentration was 60% by mass, to prepare a photosensitive resin composition.

(Photosensitivity) The photosensitive resin composition was applied on a copper-clad laminate by using a 120-mesh Tetron screen and was dried at 80° C. for 30 minutes in a hot air circulation type dryer to form a photosensitive layer having a thickness of about 30 μm. A step tablet 21 steps (manufactured by Stouffer Industries, Inc.) were closely adhered to the photosensitive layer, and the photosensitive layer was irradiated with ultraviolet radiation at a cumulative exposure dose of 500 mJ/cm². Next, spray development was performed for 60 seconds at a pressure of 1.8 kgf/cm² by using a 1% by mass aqueous solution of sodium carbonate, and unexposed parts were dissolved and developed. After development, the number of steps of the photosensitive layer remaining without being developed was checked and evaluated according to the following criteria.
A: The number of steps of the photosensitive layer remaining without being developed was 8 or more steps.
B: The number of steps of the photosensitive layer remaining without being developed was 5 to 7 steps.
C: The number of steps of the photosensitive layer remaining without being developed was 4 or fewer steps.

(TCT Resistance)

After development, the assembly was heated at 150° C. for 1 hour to produce a test specimen having a permanent mask resist in which an opening pattern was formed on a copper-clad laminated substrate. The test specimen was subjected to a temperature cycle test by maintaining at −55° C. for 30 minutes and at 125° C. for 30 minutes as one cycle, and at the time points of 1500 cycles and 2000 cycles, the test specimen was observed by visual inspection and with an optical microscope and was evaluated according to the following criteria.
A: Generation of cracks was not recognized after 2000 cycles.
B: Generation of cracks was not recognized after 1500 cycles; however, generation of cracks was recognized after 2000 cycles.
C: Generation of cracks was recognized after 1500 cycles.

(HAST Resistance)

A copper surface of a substrate for printed wiring board (manufactured by Showa Denko Materials Co., Ltd., trade name “MCL-E-679”) in which a copper foil having a thickness of 12 μm was laminated on a glass epoxy base material, was etched to prepare a substrate on which a comb-type electrode with a line/space ratio of 28 μm/32 μm was formed. On this substrate, the photosensitive resin composition was applied on a copper-clad laminate by using a 120-mesh Tetron screen and dried at 80° C. for 30 minutes in a hot air circulation type dryer to form a photosensitive layer having a thickness of about 30 μm. As described above, an evaluation substrate on which a cured film of a photosensitive element was formed was produced. The evaluation substrate was exposed for 200 hours in a state in which a voltage of DC 5 V was applied under the conditions of 135° C. and 85% RH, and then the resistance value was measured and evaluated according to the following criteria.

A: The resistance value was 1×10⁷Ω or greater.

B: The resistance value was 1×10⁶Ω or greater and less than 1×10⁷Ω.

C: The resistance value was less than 1×10⁶Ω.

TABLE 1

| Example | | 1 | 2 | 3 | 4 | 5 | 6 | 7 | 8 | 9 | 10 | 11 | 12 |
|---|---|---|---|---|---|---|---|---|---|---|---|---|---|
| (A) | A-1 | 45 | 43 | 48 | 45 | 43 | 48 | 45 | 43 | 48 | 45 | 43 | 48 |
| (B) | B-1 | 13 | — | — | 13 | — | — | 13 | — | — | 13 | — | — |
| | B-2 | — | 13 | — | — | 13 | — | — | 13 | — | — | 13 | — |
| | B-3 | — | — | 5 | — | — | 5 | — | — | 5 | — | — | 5 |
| (C) | C-1 | 4.5 | 4.5 | 4.5 | 4.5 | 4.5 | 4.5 | 4.5 | 4.5 | 4.5 | 4.5 | 4.5 | 4.5 |
| | C-2 | 0.8 | 0.8 | 0.8 | 0.8 | 0.8 | 0.8 | 0.8 | 0.8 | 0.8 | 0.8 | 0.8 | 0.8 |
| (D) | D-1 | 13 | 13 | 13 | 13 | 13 | 13 | 13 | 13 | 13 | 13 | 13 | 13 |
| | D-2 | 4 | 4 | 4 | 4 | 4 | 4 | 4 | 4 | 4 | 4 | 4 | 4 |
| (E) | E-1 | 16 | 16 | 16 | — | — | — | — | — | — | — | — | — |
| | E-2 | — | — | — | 16 | 16 | 16 | — | — | — | — | — | — |
| | E-3 | — | — | — | — | — | — | 16 | 16 | 16 | — | — | — |
| | E-4 | — | — | — | — | — | — | — | — | — | 16 | 16 | 16 |
| | E-6 | 20 | 20 | 20 | 20 | 20 | 20 | 20 | 20 | 20 | 20 | 20 | 20 |
| (F) | F-1 | 6 | 6 | 6 | 6 | 6 | 6 | 6 | 6 | 6 | 6 | 6 | 6 |
| (G) | G-1 | 1.5 | 1.5 | 1.5 | 1.5 | 1.5 | 1.5 | 1.5 | 1.5 | 1.5 | 1.5 | 1.5 | 1.5 |

| | | | | | | | | | | | | |
|---|---|---|---|---|---|---|---|---|---|---|---|---|
| TCT resistance | A | A | A | A | A | A | B | B | B | B | B | B |
| HAST resistance | A | A | A | A | A | A | A | A | A | A | A | A |
| Photosensitivity | A | A | A | B | B | B | B | B | B | B | B | B |

TABLE 2

| | | | | |
|---|---|---|---|---|
| Comparative Example | 1 | 2 | 3 | 4 |

| | | | | | |
|---|---|---|---|---|---|
| (A) | A-1 | 57 | 45 | 43 | 48 |
| (B) | B-1 | — | 13 | — | — |
| | B-2 | — | — | 13 | — |
| | B-3 | — | — | — | 5 |
| (C) | C-1 | 4.5 | 4.5 | 4.5 | 4.5 |
| | C-2 | 0.8 | 0.8 | 0.8 | 0.8 |
| (D) | D-1 | 13 | 13 | 13 | 13 |
| | D-2 | 4 | 4 | 4 | 4 |
| (E) | E-5 | 16 | 16 | 16 | 16 |
| | E-6 | 20 | 20 | 20 | 20 |
| (F) | F-1 | 6 | 6 | 6 | 6 |
| (G) | G-1 | 1.5 | 1.5 | 1.5 | 1.5 |

| | | | | |
|---|---|---|---|---|
| TCT resistance | C | C | C | C |
| HAST resistance | C | C | C | C |
| Photosensitivity | C | C | C | C |

### REFERENCE SIGNS LIST

1: photosensitive element, 10: support film, 20: photosensitive layer, 30: protective film.

1. A photosensitive resin composition for a permanent resist, the photosensitive resin composition comprising:
(A) an acid-modified vinyl group-containing resin;
(B) an elastomer;
(C) a photopolymerization initiator;
(D) a curing agent; and
(E) an inorganic filler,
wherein the inorganic filler includes a surface-treated filler.

2. The photosensitive resin composition according to claim 1, wherein the surface-treated filler has a photoreactive functional group or a thermoreactive functional group.

3. The photosensitive resin composition according to claim 1, wherein the surface-treated filler has at least one group selected from the group consisting of a (meth)acryloyl group, a vinyl group, an epoxy group, and a phenylamino group.

4. The photosensitive resin composition according to claim 1, wherein the surface-treated filler is a surface-treated silica filler.

5. The photosensitive resin composition according to claim 1, wherein a content of the surface-treated filler is 7% to 28% by mass based on a total solid content of the photosensitive resin composition.

6. The photosensitive resin composition according to claim 4, wherein the inorganic filler includes the surface-treated silica filler and barium sulfate.

7. The photosensitive resin composition according to claim 6, wherein the surface-treated silica filler has a (meth)acryloyl group, an epoxy group, or a phenylamino group.

8. The photosensitive resin composition according to claim 6, wherein the surface-treated silica filler has a (meth)acryloyl group.

9. A photosensitive element comprising a support film and a photosensitive layer formed on the support film,
wherein the photosensitive layer includes the photosensitive resin composition according to claim 1.

10. A printed wiring board comprising a permanent resist including a cured product of the photosensitive resin composition according to claim 1.

11. A method for producing a printed wiring board, the method comprising:
a step of forming a photosensitive layer on a substrate by using the photosensitive resin composition according to claim 1;
a step of exposing and developing the photosensitive layer to form a resist pattern; and
a step of curing the resist pattern to form a permanent resist.

12. A method for producing a printed wiring board, the method comprising:
a step of forming a photosensitive layer on a substrate by using the photosensitive element according to claim 9;
a step of exposing and developing the photosensitive layer to form a resist pattern; and
a step of curing the resist pattern to form a permanent resist.
